(19) United States
(12) Patent Application Publication
(10) Pub. No.: US 2026/0190743 A1
(43) Pub. Date: Jul. 2, 2026

(54) DISPLAY DEVICE

(71) Applicant: LG Display Co., Ltd., Seoul (KR)

(72) Inventors: SuChang AN, Seoul (KR); JuHan KIM, Bucheon-si (KR)

(73) Assignee: LG Display Co., Ltd., Seoul (KR)

(21) Appl. No.: 19/429,548

(22) Filed: Dec. 22, 2025

(30) Foreign Application Priority Data
Dec. 30, 2024 (KR) 10-2024-0200675

(51) Int. Cl. H10K 59/40; G06F 3/041; H10K 59/122; H10K 59/123; H10K 59/124; H10K 59/80; H10K 59/88

(52) U.S. Cl. CPC H10K 59/40; G06F 3/04164; H10K 59/122; H10K 59/123; H10K 59/124; H10K 59/80522; H10K 59/8723; H10K 59/88

(57) ABSTRACT

A display device can include a plurality of light emitting elements disposed on a substrate, each of the plurality of light emitting elements including a first electrode, an organic layer, and a second electrode, a bank disposed on the substrate, a plurality of auxiliary electrodes disposed on the bank and configured to electrically connect adjacent second electrodes, and a touch sensing unit including a plurality of touch electrodes and a plurality of touch lines. Also, each of the plurality of touch electrodes includes a group of the second electrodes electrically connected to each other by at least one of the plurality of auxiliary electrodes, and the plurality of touch lines are respectively connected to the plurality of touch electrodes and are made of a same material as the plurality of auxiliary electrodes.

### CROSS-REFERENCE TO RELATED APPLICATIONS

This application claims priority to Korean Patent Application No. 10-2024-0200675 filed on Dec. 30, 2024, in the Republic of Korea, the entirety of which is incorporated herein by reference.

### BACKGROUND

### Field

The present disclosure relates to a display device, and provides a display device in which a touch performance degradation does not occur even when the display device has a large area.

### Discussion of the Related Art

As society enters the information age, the field of display devices that visually display electrical information signals is rapidly developing, and research is being conducted to develop improved performance such as thinning, weight reduction, and low power consumption for various display devices.

Representative display devices include a liquid crystal display (LCD), a field emission display (FED), an electro-wetting display (EWD), and an organic light emitting display (OLED).

In order to provide more various functions to the user, such a display device provides a function of recognizing a user's touch on the display panel and performing input processing based on the recognized touch.

A display device capable of touch recognition includes a plurality of touch electrodes disposed on or embedded in a display panel, and by driving the touch electrodes, it is possible to detect whether a user touches the display panel and touch coordinates.

However, as the size of display devices increases, the challenge of integrating effective touch sensing capabilities also grows. This integration can lead to significant performance issues, especially in larger screens, often resulting in reduced touch sensitivity and signal delays. For example, existing touch solutions applied to large area displays can suffer from compromised touch accuracy and a degraded user experience due to the increased resistance and parasitic capacitance of the touch electrodes.

Thus, a need exists for an improved display device configuration that mitigates these limitations, particularly in devices that have large screens. Further, there is a need for a display device having an improved in-cell touch configuration in which the touch sensing unit is integrated in a way that prevents the degradation of touch performance, while also improving the manufacturing process and reducing costs.

### SUMMARY OF THE DISCLOSURE

An object to be achieved by the present disclosure is to provide a display device in which a touch performance degradation does not occur even when a display device has a large area.

Another object to be achieved by the present disclosure is to provide a display device capable of reducing a thickness of the stacked structure.

Another object to be achieved by the present disclosure is to provide a display device capable of reducing a process cost and a process time of the display device.

Objects of the present disclosure are not limited to the above-mentioned objects, and other objects, which are not mentioned above, can be clearly understood by those skilled in the art from the following descriptions.

According to an aspect of the present disclosure, a display device includes a substrate including an active area in which a plurality of sub pixels is disposed and a non-active area disposed at an outer periphery of the active area, a plurality of light emitting elements which is disposed in the plurality of sub pixels on the substrate and includes a first electrode, an organic layer, and a second electrode, a bank which is disposed to cover at least a part of the first electrode, a plurality of auxiliary electrodes which is disposed on the bank and electrically connects the second electrodes which are adjacent to each other, and a touch sensing unit disposed in the active area on the substrate, and includes a plurality of touch electrodes disposed to be spaced apart from each other, each of the plurality of touch electrodes includes a group of the second electrodes electrically connected by the plurality of auxiliary electrodes, and a plurality of touch lines which is connected to each of the plurality of touch electrodes and is formed of the same material as the plurality of auxiliary electrodes.

Other detailed matters of the embodiments are included in the detailed description and the drawings.

In the display device of the present disclosure, by applying an in-cell type touch sensing unit in which a touch sensing unit is embedded in a display panel, it is possible to prevent a decrease in touch performance even if the display device has a large area.

Further, in the display device of the present disclosure, each of the plurality of light emitting elements is electrically connected to the side surfaces of the plurality of auxiliary electrodes to reduce sheet resistance, thereby improving a voltage drop (VSS rising) phenomenon of the low potential power voltage.

Further, in the display device of the present disclosure, the driving voltage is reduced to enable low power driving, and the luminance deviation of the display device can be improved.

In addition, in the display device of the present disclosure, the stacking thickness of the display device can be reduced by using an in-cell touch, thereby increasing the degree of design freedom.

In addition, in the display device of the present disclosure, the plurality of auxiliary electrodes and the plurality of touch lines are formed by the same process and the same material to reduce the mask and reduce the process time and process cost.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram illustrating a display device according to an embodiment of the present disclosure.

FIG. 2 is a schematic view for explaining a touch electrode of a display device according to an example embodiment of the present disclosure.

FIG. 3 is a cross-sectional view taken along the line III-III′ of FIG. 2 according to an embodiment of the present disclosure.

FIG. 4A is a cross-sectional view taken along line IV-IV′ in FIG. 2 according to an embodiment of the present disclosure.

FIG. 4B is a cross-sectional view taken along line V-V′ in FIG. 2 according to an embodiment of the present disclosure.

FIG. 4C is a cross-sectional view taken along line VI-VI′ in FIG. 2 according to an embodiment of the present disclosure.

FIG. 5 is a cross-sectional view of a display device according to another example embodiment of the present disclosure.

FIG. 6 is a cross-sectional view of a display device according to still another example embodiment of the present disclosure.

FIGS. 7A and 7B are cross-sectional views of a display device according to still another example embodiment of the present disclosure.

FIG. 8 is a cross-sectional view of a display device according to still another example embodiment of the present disclosure.

FIG. 9 is a cross-sectional view of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only.” Any references to singular can include plural unless expressly stated otherwise.

Components are interpreted to include an ordinary error range even if not expressly stated.

When the position relation between two parts is described using the terms such as “on,” “above,” “below,” and “next,” one or more parts can be positioned between the two parts unless the terms are used with the term “immediately” or “directly.”

When an element or layer is disposed “on” another element or layer, another layer or another element can be interposed directly on the other element or therebetween.

Although the terms “first,” “second,” and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

Also, when an element or layer is “connected,” “coupled,” or “adhered” to another element or layer denotes that the element or layer can not only be directly connected or adhered to another element or layer, but also be indirectly connected or adhered to another element or layer with one or more intervening elements or layers “disposed,” or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

The features of various embodiments of the present disclosure can be partially or entirely adhered to or combined with each other and can be interlocked and operated in technically various ways, and the embodiments can be carried out independently of or in association with each other. Also, the term “can” used herein includes all meanings and definitions of the term “may.”

Hereinafter, example embodiments of the present disclosure will be described in detail with reference to accompanying drawings.

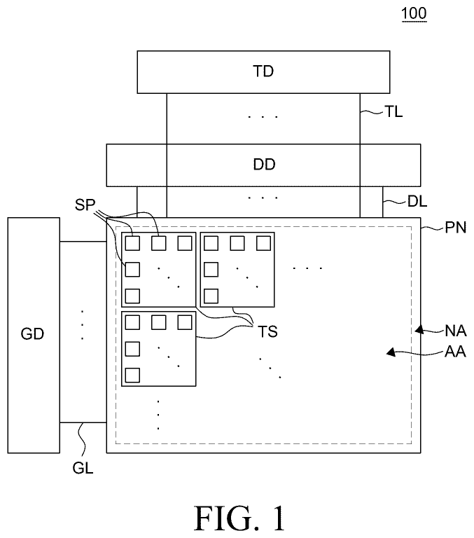

FIG. 1 is a block diagram illustrating a display device according to an example embodiment of the present disclosure.

Referring to FIG. 1, a display device 100 includes a display panel PN including a plurality of sub pixels SP, a gate driver GD, a data driver DD, and a touch driver TD.

The display panel PN is configured to display images to a user and includes a plurality of sub-pixels SP. In the display panel PN, a plurality of gate lines GL and a plurality of data lines DL cross each other, and a plurality of sub pixels SP can be formed at intersections of the gate line GL and the data line DL.

In the display panel PN, an active area AA and a non-active area NA can be defined.

The active area AA is an area in which images are displayed in the display device 100. In the active area AA, a plurality of sub pixels SP constituting a plurality of pixels and a pixel circuit for driving the plurality of sub pixels SP can be disposed. The plurality of sub-pixels SP is a minimum unit constituting the active area AA, and n sub-pixels SP can form one pixel. In each of the plurality of sub pixels SP, a thin film transistor for driving the plurality of light emitting elements is disposed so that the plurality of sub pixels SP can independently emit light.

The plurality of light emitting elements can be differently defined depending on the type of the display panel PN. For example, when the display panel PN is an organic light emitting display panel, the light emitting element can be an organic light emitting element.

In the active area AA, a plurality of signal lines for transmitting various signals to the plurality of sub-pixels SP is disposed. For example, the plurality of signal lines can include a plurality of data lines DL which supplies a data voltage to each of the plurality of sub pixels SP and a plurality of gate lines GL which supplies a gate signal to each of the plurality of sub pixels SP. The plurality of gate lines GL can extend in one direction in the active area AA and be connected to the plurality of sub pixels SP, and the plurality of data lines DL can extend in a direction different from the one direction in the active area AA and be connected to the plurality of sub pixels SP. In addition, in the active area AA, a low potential power line, a high potential power line, and the like can be further disposed, but are not limited thereto.

The non-active area NA is an area where an image is not displayed and can be defined as an area extending from the active area AA. In the non-active area NA, a link line and a pad electrode for transmitting a signal to the sub pixel SP of the active area AA, or a gate driver GD and a data driver DD can be disposed.

A touch sensing unit (e.g., touch sensors) can be embedded in the display panel PN. The touch sensing unit senses a user's touch input. Specifically, the touch sensing unit includes a plurality of touch electrodes TS and each touch electrode TS senses a user's touch. The touch electrode TS described above can be formed to have a size corresponding to the plurality of sub-pixels SP.

Specifically, when the touch sensing unit is embedded in the display panel PN, the plurality of touch electrodes TS can be disposed in an in-cell type and can be manufactured together when the display panel PN is manufactured.

The touch driver TD is connected to the touch electrode TS through the touch line TL to determine whether the user touches and a touch position. That is, when the user touches a partial area of the touch sensing unit, the touch driver TD senses a touch signal of the touch electrode TS to determine whether the user touches the touch sensing unit and a touch position.

Specifically, the touch driver TD can supply a touch driving signal to each touch electrode TS. Further, the touch driver TD can receive a touch sensing signal from each touch electrode TS. Through the above-described touch sensing signal, the touch driver TD senses a touch at the touch sensing unit.

Meanwhile, a method of sensing a touch using each touch electrode TS is divided into a mutual capacitance type for sensing a change in mutual capacitance of the touch electrode TS and a self-capacitance type for sensing a change in the self-capacitance of the touch electrode TS.

Hereinafter, a situation in which the display device 100 according to the example embodiment of the present disclosure senses a touch in a self-capacitance type will be described.

Meanwhile, the gate driver GD can sequentially supply an on voltage or a gate voltage of an off voltage to the gate line GL according to a gate control signal output from the timing controller.

The data driver DD can convert image data received from the timing controller into an analog data voltage Vdata based on the data control signal and output the analog data voltage Vdata to the data line DL.

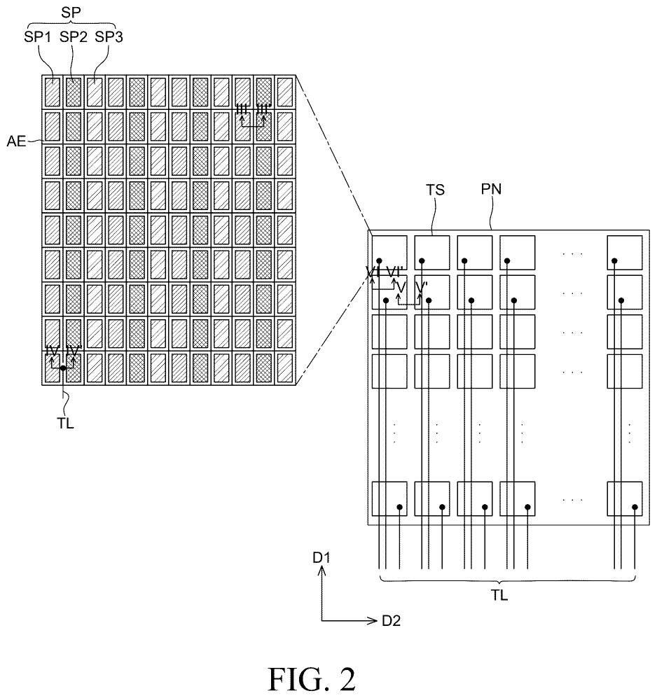

FIG. 2 is a schematic view for explaining a touch electrode of a display device according to an example embodiment of the present disclosure. In FIG. 2, the right view is a schematic view schematically illustrating a plurality of touch electrodes and a plurality of touch lines disposed on the display panel, and in FIG. 2, the left view is an enlarged view of an area corresponding to one touch electrode.

Referring to FIGS. 1 and 2 together, the touch sensing unit can be implemented to be embedded in the active area AA of the display panel PN in an in-cell type, but is not limited thereto.

In this situation, the in-cell type touch sensing unit can use a group of second electrodes formed in a block shape in the display panel PN as the touch electrode TS.

In the in-cell type touch sensing unit, the second electrode (e.g., common electrode) included in the plurality of sub-pixels SP formed inside the display panel PN forms one touch electrode TS. The touch electrode TS can be defined by a plurality of second electrodes E2 separated from the display panel PN. For example, the common electrode or cathode electrode can be divided to form multiple, distinct touch electrodes (TS) that are spaced apart from each other, allowing each one to function as an independent touch sensor.

For example, as illustrated in FIG. 2, a plurality of sub-pixels SP can be disposed to correspond to one touch electrode TS. The plurality of sub pixels SP can include a first sub pixel SP1, a second sub pixel SP2, and a third sub pixel SP3 which emit different color light. For example, the first sub-pixel SP1 can be referred to as a red sub-pixel SP1 as emitting red light, the second sub-pixel SP2 can be referred to as a green sub-pixel SP2 as emitting green light, and the third sub-pixel SP3 can be referred to as a blue sub-pixel SP3 emitting blue light, but it is not limited thereto.

The plurality of touch electrodes TS can be disposed in a matrix in the active area AA of the display panel PN, and a touch line TL for receiving a touch sensing signal can be connected to each touch electrode TS.

Meanwhile, in the in-cell type display device 100, a display driving period for displaying an image on the display panel PN and a touch driving period for sensing the display panel PN can be temporally divided. The display device 100 can be driven by temporally dividing a display driving period and a touch driving period.

Referring to FIG. 1 together, the touch driver TD can supply a touch driving signal through a touch line TL connected to the display panel PN. In this situation, during the touch driving period, a touch driving signal is supplied to the touch line TL to receive a touch sensing signal through the touch electrode TS and during the display driving period, a low potential power voltage is supplied to the touch line TL to display an image through the display panel PN.

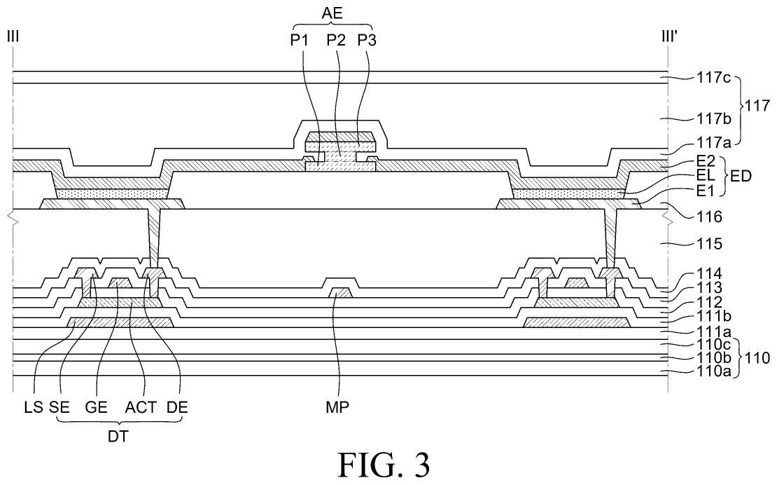

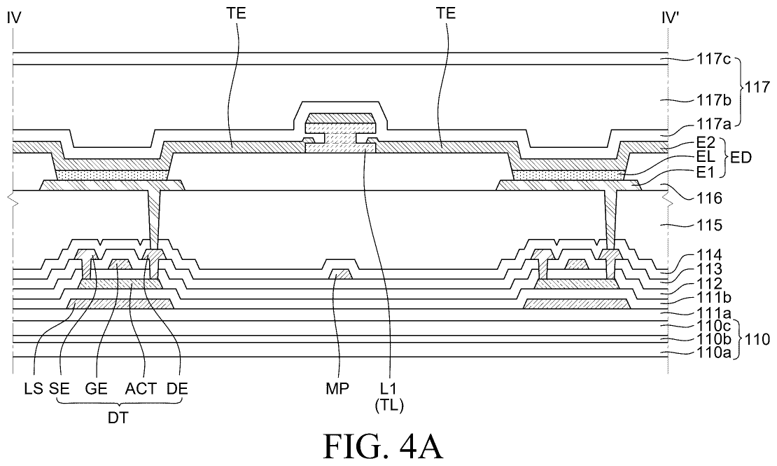

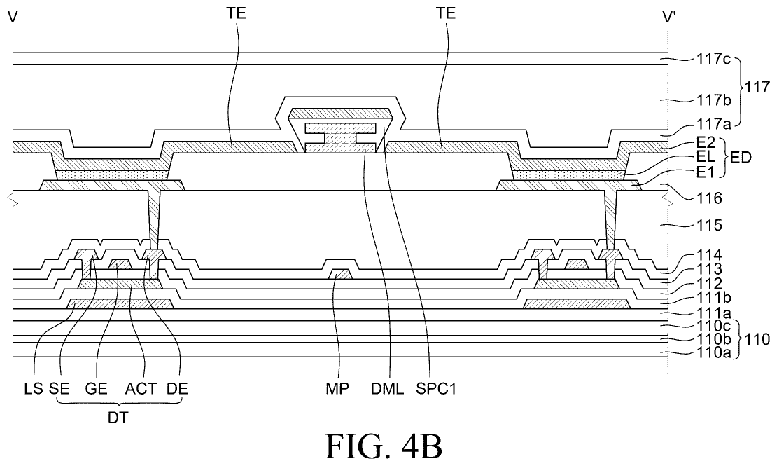

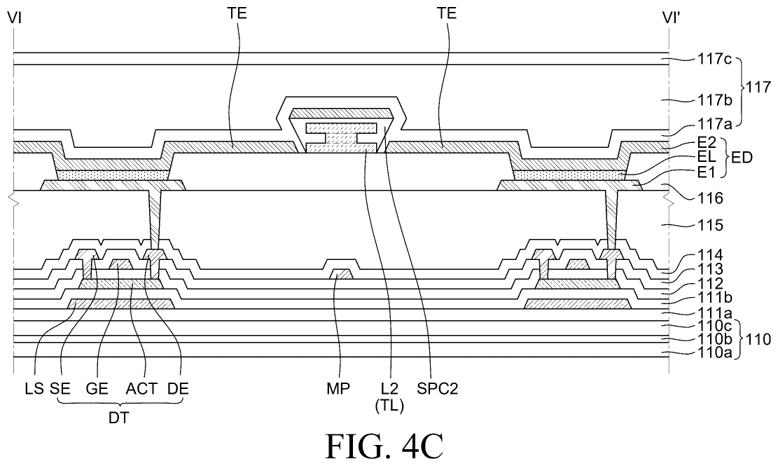

FIG. 3 is a cross-sectional view taken along the line III-III′ of FIG. 2. FIG. 4A is a cross-sectional view taken along line IV-IV′ in FIG. 2. FIG. 4B is a cross-sectional view taken along line V-V′ in FIG. 2. FIG. 4C is a cross-sectional view taken along line VI-VI′ in FIG. 2. FIG. 3 is a cross-sectional view in an area in which the touch line TL is not disposed, FIG. 4A is a cross-sectional view of a plurality of sub pixels SP in an area electrically connected to the touch line TL, FIG. 4B is a cross-sectional view in an area between a plurality of touch electrodes TS spaced apart from each other, and FIG. 4C is a cross-sectional view in an area overlapping the touch line TL but not electrically connected.

Referring to FIGS. 3 to 4C, the substrate 110 is a component for supporting various components included in the display device 100 and can be formed of an insulating material. The substrate 110 can include a first substrate 110a, an insulating layer 110b, and a second substrate 110c. The insulating layer 110b can be disposed between the first substrate 110a and the second substrate 110c. As described above, the substrate 110 is configured by the first substrate 110a, the second substrate 110c, and the insulating layer 110b to suppress moisture permeation. For example, the first substrate 110a and the second substrate 110c can be polyimide (PI) substrates.

The first buffer layer 111a is disposed on the substrate 110. The first buffer layer 111a can reduce permeation of moisture, oxygen, or impurities through the substrate 110. For example, the first buffer layer 111a can be configured as a single layer or multilayer made of silicon oxide (SiOx) or silicon nitride (SiNx). However, the present disclosure is not limited thereto.

The light shielding layer LS is disposed on the first buffer layer 111a in each of the plurality of sub-pixels. The light shielding layer LS blocks light incident onto an active layer ACT of the transistor DT, which will be described below, below the substrate 110. Light incident onto the active layer ACT of the transistor DT is blocked by the light shielding layer LS to minimize or reduce a leakage current.

The second buffer layer 111b is disposed on the substrate 110 and the light shielding layer LS. The second buffer layer 111b can reduce penetration of moisture or impurities through the substrate 110. For example, the second buffer layer 111b can be configured by a single layer or a multilayer of silicon oxide (SiOx) or silicon nitride (SiNx), but is not limited thereto. However, the second buffer layer 111b can be omitted depending on the type of substrate 110 or the type of transistor, but is not limited thereto.

The transistor DT of each of the plurality of sub-pixels SP is disposed on the second buffer layer 111b. The transistor DT is a transistor for controlling a driving current supplied to the light emitting element ED.

The transistor DT includes an active layer ACT, a gate electrode GE, a source electrode SE, and a drain electrode DE.

The active layer ACT of the transistor DT can be disposed on the second buffer layer 111b. For example, the active layer ACT can be formed of polysilicon (p-Si), amorphous silicon (a-Si), or an oxide semiconductor, but is not limited thereto.

The gate insulating layer 112 can be disposed on the active layer ACT. The gate insulating layer 112 is an insulating layer which insulates the active layer ACT from the gate electrode GE and can be formed of silicon oxide (SiOx), silicon nitride (SiNx), or a multilayer thereof.

Further, the gate electrode GE of the transistor DT can be disposed on the gate insulating layer 112. The gate electrode GE is disposed on the gate insulating layer 112 to overlap with the active layer ACT. The gate electrode GE can be formed of various conductive materials, such as magnesium (Mg), aluminum (Al), nickel (Ni), chromium (Cr), molybdenum (Mo), tungsten (W), gold (Au), or an alloy thereof, but is not limited thereto.

The interlayer insulating layer 113 can be disposed to cover the gate electrode GE. The interlayer insulating layer 113 is an insulating layer which protects components below the interlayer insulating layer 113 and can be configured by a single layer or a multilayer of silicon oxide (SiOx) or silicon nitride (SiNx), but is not limited thereto.

The source electrode SE and the drain electrode DE of the transistor DT can be disposed on the interlayer insulating layer 113.

The source electrode SE and the drain electrode DE can be connected to one side and the other side of the active layer ACT, respectively, through contact holes provided in the interlayer insulating layer 113 and the gate insulating layer 112. The source electrode SE and the drain electrode DE can be formed of various conductive materials, such as magnesium (Mg), aluminum (Al), nickel (Ni), chromium (Cr), molybdenum (Mo), tungsten (W), gold (Au), or an alloy thereof, but are not limited thereto.

A portion of the active layer ACT overlapping with the gate electrode GE is a channel region. One of the source electrode SE and the drain electrode DE is connected to one side of the channel region in the active layer ACT, and the other is connected to the other side of the channel region in the active layer ACT.

A metal pattern MP made of the same material can be disposed on the same layer as the source electrode SE and the drain electrode DE. For example, the metal pattern MP can be electrically floated. For example, the metal pattern MP can be a line to which a direct current voltage is applied to drive the display device 100, independently of the plurality of touch lines TL. For example, the metal pattern MP can be an extra wiring line that can be either electrically floated and not connected to anything, or it can be used for carrying a voltage for operating the display device 100.

The passivation layer 114 can be disposed on the source electrode SE, the drain electrode DE, and the metal pattern MP. The passivation layer 114 is provided to protect the transistor DT and can be formed of an inorganic layer, for example, silicon oxide (SiOx), silicon nitride (SiNx), or a multilayer thereof.

The planarization layer 115 can be disposed on the passivation layer 114. The planarization layer 115 can protect the transistor DT and planarize an upper portion thereof. Even though in the drawing, the planarization layer 115 is illustrated as a single layer, the planarization layer 115 can be configured by a multilayer, and for example, can be formed of photoresist or an acrylic-based organic material, but is not limited thereto.

The light emitting element ED including the first electrode E1, the organic layer EL, and the second electrode E2 can be positioned on each sub pixel SP above the planarization layer 115.

Hereinafter, a stack structure of the light emitting element ED will be described in detail with reference to FIGS. 3 to 4C.

The first electrode E1 can be disposed on the planarization layer 115. For example, the first electrode E1 can be referred to as an anode. In this situation, the first electrode E1 can be electrically connected to the drain electrode DE of the transistor DT through a contact hole provided in the planarization layer 115. The first electrode E1 can be formed of a metallic material.

For example, when the display device 100 is a top emission type in which light emitted from the light emitting element ED is emitted above the substrate 110 on which the light emitting element ED is disposed, the first electrode E1 can include a transparent conductive layer and a reflective layer. The transparent conductive layer can be made of a transparent conductive oxide such as ITO or IZO, and the reflective layer can be made of, for example, silver (Ag), aluminum (Al), gold (Au), molybdenum (Mo), tungsten (W), chromium (Cr), or an alloy thereof.

The bank 116 can be disposed while covering at least a part of the first electrode E1 to define an emission area. A portion of the bank 116 corresponding to the emission area of the sub-pixel SP can be opened. A part of the first electrode E1 can be exposed through the open part of the bank 116 (hereinafter, referred to as an open area). In this situation, the bank 116 can be made of an inorganic insulating material, such as silicon nitride (SiNx) or silicon oxide (SiOx), or an organic insulating material, such as benzocyclobutene-based resin, acrylic-based resin, or imide-based resin, but is not limited thereto.

The organic layer EL can be disposed on the first electrode E1 exposed through the open area of the bank 116.

The organic layer EL is a layer for emitting light of a specific color and can have a structure separated for each sub pixel SP. The organic layer EL can include a plurality of organic material layers such as a hole transport layer, a hole injection layer, an electron transport layer, or an electron injection layer. For example, the organic layer EL disposed in the red sub pixel SP1 emitting red light can include a light emitting layer emitting red light, the organic layer EL disposed in the green sub pixel SP2 emitting green light can include a light emitting layer emitting green light, and the organic layer EL disposed in the blue sub pixel SP3 emitting blue light can include a light emitting layer emitting blue light. The organic layer EL disposed in the red sub-pixel SP1, the green sub-pixel SP2, and the blue sub-pixel SP3 can be disposed to be separated from each other.

The second electrode E2 can be disposed to cover the organic layer EL. For example, the second electrode E2 can be referred to as a cathode (e.g., a common cathode).

For example, the second electrode E2 is electrically connected to the side surface of the auxiliary electrode AE having a low resistance in each of the sub-pixels SP to improve the voltage drop phenomenon of the low-potential power voltage as the sheet resistance decreases. Accordingly, the driving voltage and power consumption can be reduced, and the luminance deviation of the display device 100 can be improved. For example, connecting the second electrode E2 to the low resistance auxiliary electrode AE in each sub-pixel can lower the overall resistance. This reduces voltage drop, which in turn leads to lower power consumption, a reduced driving voltage and more uniform screen brightness.

The second electrode E2 can include a transparent conductive material that transmits light. For example, at least one of indium tin oxide (ITO) and indium zinc oxide (IZO) can be formed, but is not limited thereto. Alternatively, the second electrode E2 can include a semi-transmissive metal material that transmits light. For example, the second electrode E2 can be formed of at least one of bismuth (Bi), titanium (Ti), molybdenum (Mo), tungsten (W), silver (Ag), magnesium (Mg), aluminum (Al), platinum (Pt), palladium (Pd), gold (Au), nickel (Ni), neodymium (Nd), iridium (Ir), chromium (Cr), lithium (Li), and calcium (Ca), but is not limited thereto.

Referring to FIGS. 2 and 3 together, a plurality of auxiliary electrodes AE can be disposed in an area which does not overlap with the plurality of touch lines TL on the bank 116.

The second electrodes E2 adjacent to each other on the bank 116 can be electrically connected to each other by a plurality of auxiliary electrodes AE.

In the active area AA, the plurality of auxiliary electrodes AE can be a plurality of low potential power lines to which a plurality of low potential power voltages is applied.

For example, the second electrode E2 is electrically connected to the side surface of the auxiliary electrode AE having a low resistance in each of the sub-pixels SP to improve the voltage drop phenomenon of the low-potential power voltage as the sheet resistance decreases. Accordingly, the driving voltage and power consumption can be reduced, and the luminance deviation of the display device 100 can be improved. For example, this design can improve power efficiency and picture quality by using the auxiliary electrode AE to solve a voltage-drop problem. The second electrode E2 layer can be thin and have high resistance, causing voltage to drop unevenly across a large screen. This can lead to inconsistent brightness and waste power. By connecting this second electrode E2 to a much thicker, low-resistance auxiliary electrode AE, the voltage can be distributed efficiently and evenly. As a result, the display device can achieve uniform brightness and can operate using less power.

The plurality of auxiliary electrodes AE can include a first layer P1, a second layer P2 on the first layer P1, and a third layer P3 on the second layer P2 (e.g., a triple layer auxiliary electrode AE). In this situation, referring to FIG. 3, the width of the second layer P2 can be smaller than the width of the first layer P1 and the width of the third layer P3. For example, each of the first layer P1, the second layer P2, and the third layer P3 can include any one of molybdenum (Mo), copper (Cu), titanium (Ti), aluminum (Al), chromium (Cr), gold (Au), nickel (Ni), and neodymium (Nd), or an alloy thereof, but is not limited thereto. For example, the plurality of auxiliary electrodes AE can have a three-layer structure of titanium (Ti)/aluminum (Al)/titanium (Ti) in which the first layer P1 is titanium (Ti), the second layer P2 is aluminum, and the third layer P3 is titanium (Ti).

Meanwhile, referring to FIGS. 2 and 3 together, a plurality of touch electrodes TS are disposed in the active area AA. For example, each of the plurality of touch electrodes TS can include a group TE of the second electrode electrically connected by the plurality of auxiliary electrodes AE. That is, the group TE of the second electrode disposed in the active area AA is divided into a plurality of blocks according to the area to configure the plurality of touch electrodes TS disposed to be spaced apart from each other. For example, the plurality of touch electrodes TS can be disposed to be spaced apart from each other in the first direction D1 and the second direction D2 intersecting the first direction D1.

In this situation, the groups TE of the second electrodes disposed in one touch electrode TS can be electrically connected to each other. Further, the plurality of touch electrodes TS can be electrically connected to each of the plurality of touch lines TL made of the same material as the plurality of auxiliary electrodes AE. Accordingly, the plurality of touch electrodes TS can receive a touch driving signal through the plurality of touch lines TL to sense a touch. Further, the plurality of touch electrodes TS can transmit the sensed touch sensing signal to the plurality of touch lines TL. The plurality of touch electrodes TS can recognize a touch through a self-capacitance type. For example, the active area of the display can contain multiple touch electrodes TS. Each touch electrode can be formed by grouping the display's existing second electrodes E2 together. These can be wired into a single block by auxiliary electrodes AE. These touch electrode blocks (e.g., touch electrodes TS) are arranged in a grid and are connected to touch lines TL, which send and receive the touch signals. These touch lines can be made of the same material as the auxiliary electrodes.

Meanwhile, referring to FIGS. 2 and 4A together, only one touch line TL can be electrically connected to one touch electrode TS in the plurality of touch electrodes TS disposed to be spaced apart from each other in the first direction D1. For example, the display device 100 according to the example embodiment of the present disclosure can include a touch electrode TS area overlapping with the touch line TL and electrically connected to the touch line TL as shown in FIG. 4A, an area between a plurality of touch electrodes TS spaced apart from each other as shown in FIG. 4B, and a touch electrode TS area overlapping with the touch line TL and insulated from the touch line TL, as shown in FIG. 4C. For example, each touch electrode TS is connected to one dedicated touch line TL. FIG. 4A shows an example of where a touch line TL connects to its corresponding touch electrode TS, FIG. 4B shows an example of an area between two adjacent touch electrodes TS that should not connect to each other, and FIG. 4C shows an example of a touch line TL that passes between and over two adjacent touch electrodes TS that are not to be connected to the touch line TL.

Referring to FIGS. 2 and 4A together, the plurality of touch lines TL extend in the first direction D1 and can overlap with the plurality of touch electrodes TS in the first direction D1. In this situation, the plurality of touch lines TL can be electrically connected to only one touch electrode TS among the plurality of touch electrodes TS arranged in the first direction D1.

Each touch line TL can include a first line L1 (e.g., lower wiring layer) that electrically connects it to one of the touch electrodes TS. The first line L1 can also be referred to as a first line segment.. In this situation, the first line L1 can be formed of the same material on the same layer as the plurality of auxiliary electrodes AE.

In this situation, the first line L1 can be electrically connected to the touch driver, and each of the plurality of touch electrodes TS can be applied with a touch driving signal by the corresponding first line L1.

Meanwhile, referring to FIGS. 2 and 4B together, a plurality of first spacers SPC1 having an inverted trapezoidal shape can be disposed on the bank 116 in an area in which the plurality of touch electrodes TS are spaced apart from each other. However, the present disclosure is not limited thereto. A metal deposition prevention pattern can be disposed instead of the plurality of first spacers SPC1 in an area in which the plurality of touch electrodes TS is spaced apart from each other. For example, a metal deposition prevention pattern is disposed in an area in which the plurality of touch electrodes TS are distinguished from each other, and a metal layer is then deposited. In this situation, the metal layer is not deposited on the metal deposition prevention pattern due to the low surface energy of the metal deposition prevention pattern, and the metal layer can be disposed in the form of the second electrode E2 in the portion where the metal deposition prevention pattern is not disposed, that is, inside the plurality of touch electrodes TS. In other words, to separate the touch electrodes TS from each other, first spacers SPC1 can be disposed on the bank 116 in the gaps between adjacent touch electrodes TS. Also, according to an embodiment, a metal deposition prevention pattern can be used in these gaps. This metal deposition prevention pattern can include a material that has a low surface energy that repels metal. When the second electrode E2 layer is deposited, it will not stick to this pattern, which can ensure that the metal only forms within the desired touch electrode areas and leaving them separated at the desired locations.

For example, the plurality of first spacers SPC1 can be formed of the same material as the bank 116, but are not limited thereto.

A plurality of dummy lines DML covered by a plurality of first spacers SPC1 disposed on the bank 116 in a region in which the plurality of touch electrodes TS are spaced apart from each other can be further included. For example, a plurality of dummy lines DML can be electrically floated and not connected to anything.

The plurality of dummy lines DML can be formed of the same material on the same layer as the plurality of auxiliary electrodes AE. For example, the dummy lines DML can be non-functional, electrically floated metal traces located in the gaps between adjacent touch electrodes that are to remain spaced apart from each other. The dummy lines can be made from the same material and during the same manufacturing step as the functional auxiliary electrodes AE, which can keep the metal pattern on that layer uniform and help to make the manufacturing process more stable and reliable.

Referring to FIGS. 2 and 4C together, each of the plurality of touch lines TL can include a second line L2 insulated from the plurality of touch lines TL among the plurality of touch electrodes TS. In this situation, the second line L2 can be disposed on the same layer as the first line L1 and the plurality of auxiliary electrodes AE. In other words, a touch line TL can include a second line L2 segment. This L2 segment is part of the touch line TL that passes over a touch electrode TS that it is not supposed to be electrically connected to.

The display device can further include a plurality of second spacers SPC2 having an inverted trapezoidal shape, plurality of second spacers SPC2 being disposed on the bank 116 to cover the second line L2 in an area insulated from the plurality of touch lines TL while overlapping the plurality of touch lines TL. For example, the plurality of second spacers SPC2 can have an inverted trapezoidal shape in which a width of an upper surface is wider than a width of a lower surface. The group TE of the second electrodes and the second line L2 can be insulated from each other on the side surfaces of the plurality of second spacers SPC2 by the shape of the plurality of second spacers SPC2. Accordingly, the second line L2 can be insulated from the plurality of touch electrodes TS. For example, the plurality of second spacers SPC2 can be formed of the same material as the plurality of first spacers SPC1. For example, FIG. 4C shows an example of where a touch line TL passes over a group of the second electrodes that it should not be electrically connected to.

In the display device 100 according to the example embodiment of the present disclosure, by dividing areas of the plurality of touch electrodes TS, the plurality of touch electrodes TS can independently sense whether there is a touch. For example, the plurality of first spacers SPC1 are disposed to cover the plurality of dummy lines DML formed of the same material as the plurality of auxiliary electrodes AE in an area where the plurality of touch electrodes TS are divided. Accordingly, the plurality of first spacers SPC1 can disconnect the group TE of the second electrodes electrically connected by the plurality of auxiliary electrodes AE. For example, the group TE of the second electrode can be electrically insulated from the group TE of adjacent second electrodes on the side surfaces of the plurality of first spacers SPC1. That is, areas of the plurality of touch electrodes TS are divided by the plurality of first spacers SPC1, and the plurality of touch electrodes TS can independently sense whether there is a touch. In other words, to allow each touch electrode TS to sense touch independently, first spacers SPC1 can be used to divide them. These spacers are placed in the gaps between the touch electrodes to physically disconnect the second electrode groups from each other.

The encapsulation unit 117 can be positioned above the light emitting element ED and the touch sensing unit.

The encapsulation unit 117 can have a single-layered structure or a multi-layered structure. For example, the encapsulation unit 117 can include a first inorganic encapsulation layer 117a, a second inorganic encapsulation layer 117c, and an organic encapsulation layer 117b.

For example, among the first inorganic encapsulation layer 117a, the second inorganic encapsulation layer 117c, and the organic encapsulation layer 117b, the organic encapsulation layer 117b can be the thickest and can serve as a planarization layer.

The first inorganic encapsulation layer 117a can be disposed on the second electrode E2 and disposed to be most adjacent to the light emitting element ED. The first inorganic encapsulation layer 117a can be formed of an inorganic insulating material on which low-temperature deposition can be performed. For example, the first inorganic encapsulation layer 117a can be made of silicon nitride (SiNx), silicon oxide (SiOx), silicon oxynitride (SiON), or aluminum oxide (Al2O3). Since the first inorganic encapsulation layer 117a is deposited in a low temperature atmosphere, it is possible to prevent or reduce damage to the organic layer EL including an organic material vulnerable to a high temperature atmosphere during the deposition process.

The organic encapsulation layer 117b can be formed to have a smaller area than the first inorganic encapsulation layer 117a. In this situation, the organic encapsulation layer 117b can be formed to expose both ends of the first inorganic encapsulation layer 117a. The organic encapsulation layer 117b can serve as a buffer to alleviate stress between layers and to enhance planarization performance.

For example, the organic encapsulation layer 117b can be made of an organic insulating material such as acrylic resin, epoxy resin, polyimide, polyethylene, or silicon oxycarbon (SiOC). For example, the organic encapsulation layer 117b can be formed by an inkjet method, but is not limited thereto.

The second inorganic encapsulation layer 117c can be formed above the substrate 110 on which the organic encapsulation layer 117b is formed to cover upper surfaces and side surfaces of the first inorganic encapsulation layer 117a and the organic encapsulation layer 117b. In this situation, the second inorganic encapsulation layer 117c can minimize or block the permeation of external moisture or oxygen into the first inorganic encapsulation layer 117a and the organic encapsulation layer 117b. For example, the second inorganic encapsulation layer 117c can be made of an inorganic insulating material such as silicon nitride (SiNx), silicon oxide (SiOx), silicon oxynitride (SiON), or aluminum oxide (Al2O3).

In general, the display device uses a mutual-capacitance type in which a touch sensing unit including a plurality of touch electrodes is disposed on an encapsulation unit for a touch function, and a driving line and a sensing line are connected to each of the plurality of touch electrodes to determine the presence of a touch and a touch position using the capacitance between the plurality of touch electrodes. However, in this situation, an additional process for forming the touch sensing unit on the encapsulation unit is required, and as the display device becomes larger, the lengths of the driving line and the sensing line increase, resulting in a problem in that the touch performance deteriorates as the resistance and capacitance increase.

Accordingly, in the display device 100 according to the example embodiment of the present disclosure, an in-cell type touch sensing unit in which the touch sensing unit is embedded is applied to the inside of the display panel and the touch is sensed in a self-capacitance type that senses a change in the self-capacitance. Therefore, even though the display device 100 is large-area, the length of the plurality of touch lines TL may not be significantly increased compared to the mutual capacitance type. Accordingly, even if the display device 100 has a large area, a decrease in touch performance can be prevented or reduced.

Further, in the display device 100 according to the example embodiment of the present disclosure, the second electrodes E2 of the plurality of light emitting elements ED are electrically connected to the side surfaces of the plurality of auxiliary electrodes AE having low resistance, respectively, to improve the voltage drop phenomenon of the low potential power voltage as the sheet resistance deteriorates. Accordingly, the driving voltage and power consumption can be reduced, and the luminance deviation of the display device 100 can be improved.

Further, in the display device 100 according to the example embodiment of the present disclosure, the group TS of the second electrodes electrically connected by the plurality of auxiliary electrodes AE is used as the plurality of touch electrodes TS and includes a plurality of touch lines TL made of the same material as the plurality of auxiliary electrodes AE to configure the touch sensing unit. Accordingly, the thickness of the stacked structure of the display device 100 can be reduced, so that the degree of design freedom can be increased.

Further, in the display device 100 according to the example embodiment of the present disclosure, the plurality of auxiliary electrodes AE and the plurality of touch lines TL are formed by the same process and the same material to reduce the mask, thereby reducing the process time and the process cost.

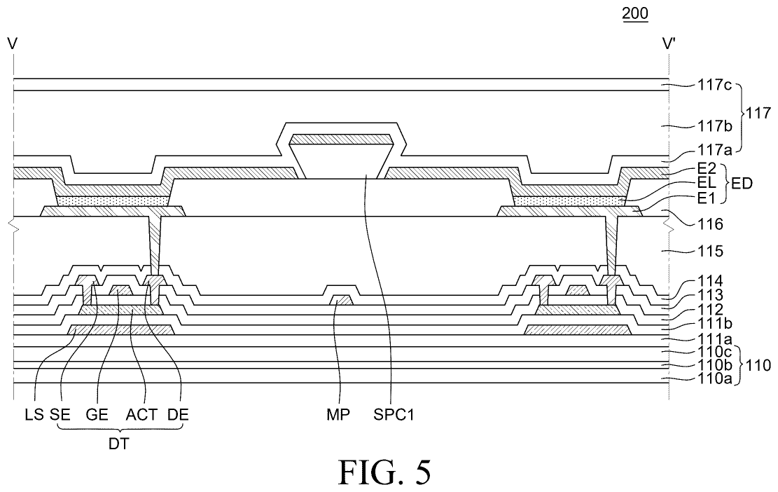

FIG. 5 is a cross-sectional view of a display device according to another example embodiment of the present disclosure. FIG. 5 is a cross-sectional view illustrating V-V′ of FIG. 2 according to another embodiment of the present disclosure. In FIG. 5, the other configurations are substantially the same as those in FIGS. 1 to 4C except for an area between adjacent touch electrodes TS that are spaced apart from each other in FIG. 4B. Therefore, for convenience of description, a redundant description other than an area between the plurality of touch electrodes TS which is spaced apart from each other will be omitted.

Referring to FIGS. 2, 3, and 5, in the display device 200 according to another example embodiment of the present disclosure, a plurality of first spacers SPC1 having an inverted trapezoidal shape can be disposed on the bank 116 in an area in which the plurality of touch electrodes TS is spaced apart from each other.

The plurality of first spacers SPC1 can have an inverted trapezoidal shape in which a width of an upper surface is wider than a width of a lower surface. The group TE of the second electrode electrically connected by the plurality of auxiliary electrodes AE on the side surfaces of the plurality of first spacers SPC1 can be electrically insulated from the group TE of the adjacent second electrode by the shape of the plurality of first spacers SPC1. That is, areas of the plurality of touch electrodes TS are divided by the plurality of first spacers SPC1, and the plurality of touch electrodes TS can independently sense whether to touch.

For example, the plurality of first spacers SPC1 are disposed on the bank 116 in an area where the plurality of touch electrodes TS is separated. Thereafter, the plurality of auxiliary electrodes AE and the plurality of touch lines TL formed of the same material as the plurality of auxiliary electrodes AE can be disposed on the bank 116, and the second electrode E2 can be deposited. Accordingly, the plurality of first spacers SPC1 can disconnect the group TE of the second electrodes electrically connected by the plurality of auxiliary electrodes AE. For example, the group TE of the second electrode can be electrically insulated from the group TE of adjacent second electrodes on the side surfaces of the plurality of first spacers SPC1. That is, areas of the plurality of touch electrodes TS are divided by the plurality of first spacers SPC1, and the plurality of touch electrodes TS can independently sense a touch.

Accordingly, in the display device 200 according to another example embodiment of the present disclosure, first the area for classifying the plurality of touch electrodes TS is divided, and then the plurality of auxiliary electrodes AE and the plurality of touch lines TL can be formed for each touch electrode TS. Accordingly, a dummy line electrically floating between the plurality of touch electrodes TS can be removed. In other words, according to an embodiment, a dummy line does not have to be included inside of the first spacer SPC1.

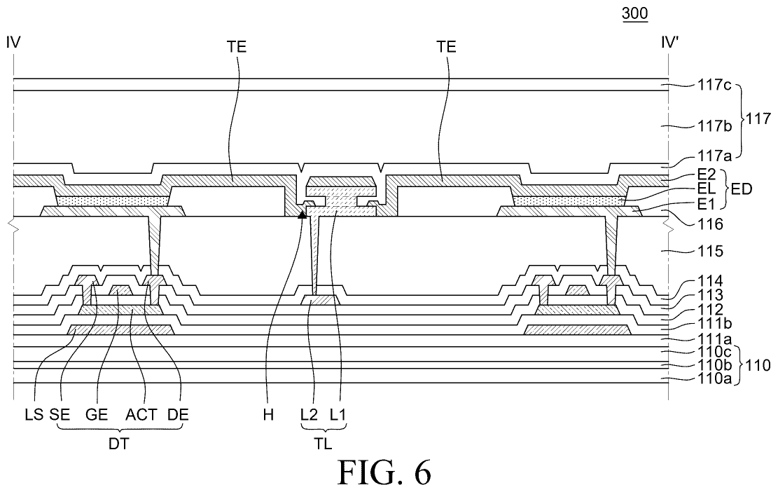

FIG. 6 is a cross-sectional view of a display device according to still another example embodiment of the present disclosure. FIG. 6 is a cross-sectional view illustrating IV-IV′ of FIG. 2 according to another embodiment of the present disclosure. In FIG. 6, as compared with FIGS. 1 to 4C, configurations other than the touch sensing unit in an area which overlaps the touch line TL of FIG. 4A and is electrically connected to the touch line TL are substantially the same. Therefore, for convenience of description, a redundant description other than the touch sensing unit in an area which overlaps the touch line TL and is electrically connected to the touch line TL will be omitted.

Referring to FIGS. 2, 3, and 6, the display device 300 according to still another example embodiment of the present disclosure can further include a hole H passing through the bank 116 in an area electrically connected to the touch line TL.

In this situation, the plurality of touch lines TL can include a first line L1 disposed in the hole H and a second line L2 disposed below the first line L1. For example, the first line L1 can be formed of the same material as the plurality of auxiliary electrodes AE, and the second line L2 can be formed of the same material on the same layer as the source electrodes SE and the drain electrodes DE of the plurality of transistors DT.

Referring to FIGS. 2 and 6 together, in the display device 300 according to still another example embodiment of the present disclosure, the plurality of touch lines TL extend in the first direction D1 and overlap with the plurality of touch electrodes TS in the first direction D1. In this situation, each of the plurality of touch lines TL is electrically connected to only one touch electrode TS among the plurality of touch electrodes TS arranged in the first direction D1 and can be insulated from the other touch electrodes TS.

The first line L1 can be disposed to overlap with the touch electrode TS which is electrically connected to the first line L1 among the plurality of touch electrodes TS and the second line L2 can be electrically connected to the first line L1 at an end of the touch electrode TS which is electrically connected to the first line L1 among the plurality of touch electrodes TE.

That is, one touch electrode TS among the plurality of touch electrodes TS can be electrically connected to the first line L1, and at an end thereof, the first line L1 can be electrically connected to the second line L2 disposed below the first line L1.

In this situation, the second line L2 can be electrically connected to the touch driver, and the plurality of touch electrodes TS can be applied with the touch driving signal by the second line L2.

For example, the embodiment shown in FIG. 6 shows an alternative way to connect the touch lines TL to the touch electrodes TS. A hole H is formed through the bank 116 at the connection point, allowing the touch line to be a two-part structure. For example, a first line L1, made of the same material as the auxiliary electrodes, sits in the hole H and makes contact with the touch electrode. This first L1 then connects to a second line L2 that runs underneath, on the same layer as the pixel transistors. The second L2 line can route the signal to the main touch driver. Using the existing transistor layer for signal routing in this way can make it much easier to insulate the touch line from other touch electrodes that it needs to pass over.

Accordingly, in the display device 300 according to still another example embodiment of the present disclosure, the touch sensing unit can be electrically connected to the touch driving unit using the second line L2 positioned on the same layer as the components of the plurality of transistors DT. In addition, one touch line TL can be electrically connected to only one touch electrode TS and can be easily insulated from other touch electrodes TS.

In the display device 300 according to still another example embodiment of the present disclosure, by applying the in-cell type touch sensing unit in which the touch sensing unit is embedded in the display panel, even if the display device 300 becomes large, a decrease in touch performance can be prevented or reduced.

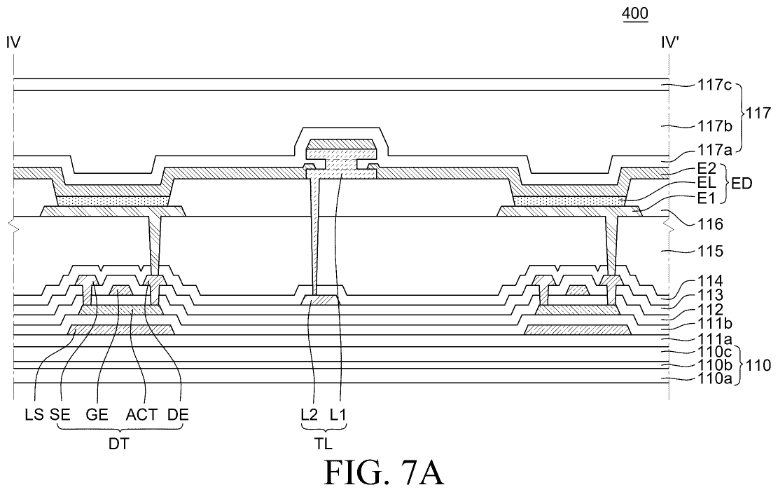

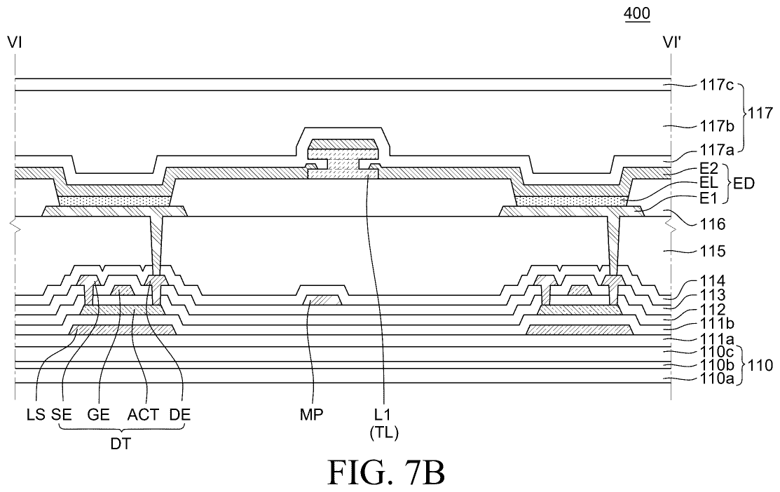

FIGS. 7A and 7B are cross-sectional views of a display device according to other example embodiments of the present disclosure. FIG. 7A is a cross-sectional view showing IV-IV′ of FIG. 2 according to another embodiment of the present disclosure, and FIG. 7B is a cross-sectional view showing VI-VI′ of FIG. 2 according to another embodiment of the present disclosure. Compared to FIGS. 1 to 4C, other configurations of FIG. 7A except for a touch sensing unit in an area overlapping the touch line TL of FIG. 4A and electrically connected to the touch line TL are substantially the same, and FIG. 7B is substantially the same as those of FIGS. 1 to 4C except for a touch sensing unit in an area overlapping the touch line TL of FIG. 4C and insulated from the touch line TL. Therefore, for convenience of description, a redundant description will be omitted.

First, referring to FIGS. 2, 3, and 7A, in the display device 400 according to still another example embodiment of the present disclosure, each of the plurality of touch lines TL can include a first line L1 disposed on the same layer as the plurality of auxiliary electrodes AE and a second line L2 disposed below the first line L1. For example, the first line L1 can be formed of the same material on the same layer as the plurality of auxiliary electrodes AE, and the second line L2 can be positioned on the same layer as the source electrodes SE and the drain electrodes DE of the plurality of transistors DT.

Referring to FIGS. 2 and 7A together, in the display device 400 according to still another example embodiment of the present disclosure, the plurality of touch lines TL extend in the first direction D1 and overlap the plurality of touch electrodes TS in the first direction D1. In this situation, each of the plurality of touch lines TL can be electrically connected to only one touch electrode TS among the plurality of touch electrodes TS arranged in the first direction D1.

Referring to FIG. 7A, the first line L1 can be disposed to overlap with the touch electrode TS which is electrically connected to the first line L1 among the plurality of touch electrodes TS and the second line L2 can be electrically connected to the first line L1 at an end of the touch electrode TS which is electrically connected to the first line L1 among the plurality of touch electrodes TS.

That is, one touch electrode TS of the plurality of touch electrodes TS can be electrically connected to the first line L1, and at an end thereof, the first line L1 can be electrically connected to the second line L2 disposed below the first line L1.

In this situation, the second line L2 can be electrically connected to the touch driver, and the plurality of touch electrodes TS can be applied with the touch driving signal through the second line L2. In other words, the embodiment of FIG. 7A is similar to the embodiment of FIG. 6, except the auxiliary electrode AE is disposed on bank 116 rather than inside a hole in the bank 116.

Meanwhile, referring to FIGS. 2 and 7B, the second line L2 can be insulated from the first line L1. For example, the second line L2 (e.g., MP) can be disposed below the touch electrode TS which is electrically insulated from the second line L2 (e.g., MP) among the plurality of touch electrodes TS. In this situation, the second line L2 (e.g., MP) can be disposed to overlap with the first line L1.

For example, among the plurality of touch electrodes TS, the touch electrode TS in which the first line L1 and the second line L2 (e.g., MP) are insulated can be insulated without receiving a touch driving signal from the second line L2 (e.g., MP).

Accordingly, in the display device 400 according to still another example embodiment of the present disclosure, the touch sensing unit can be electrically connected to the touch driving unit using the second line L2 positioned on the same layer as the components of the plurality of transistors DT. In addition, one touch line TL can be electrically connected to only one touch electrode TS and can be easily insulated from other touch electrodes TS. In other words, the embodiment of FIG. 7B is similar to the embodiment of FIG. 7A, except the second line L2 (e.g., MP) is not connected to the first line L1.

In the display device 400 according to still another example embodiment of the present disclosure, by applying an in-cell type touch sensing unit in which a touch sensing unit is embedded in the display panel, even if the display device 400 is large, a decrease in touch performance can be prevented or reduced.

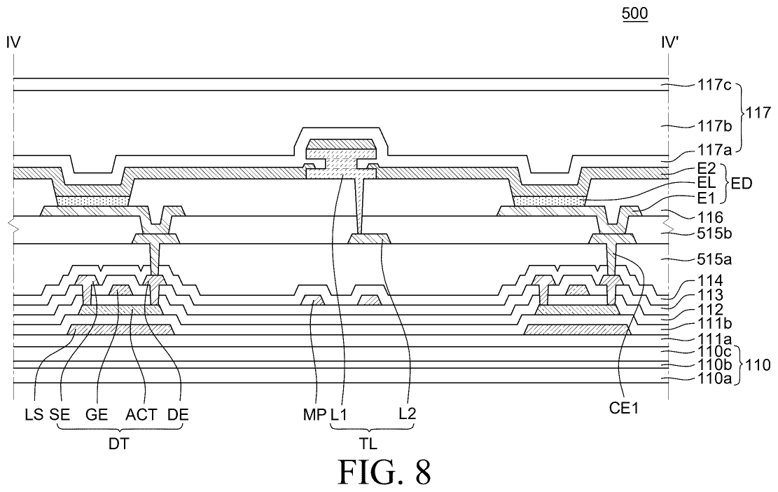

FIG. 8 is a cross-sectional view of a display device according to still another example embodiment of the present disclosure. FIG. 8 is a cross-sectional view illustrating IV-IV′ of FIG. 2 according to another embodiment of the present disclosure. As compared with FIG. 7A, the configuration of FIG. 8 is substantially the same as that of FIG. 7A except for a first planarization layer 515a, a second planarization layer 515b, and a second connection electrode CE2. Therefore, for convenience of description, a redundant description excluding the first planarization layer 515a, the second planarization layer 515b, and the second connection electrode CE2 will be omitted.

Referring to FIG. 8, a first planarization layer 515a can be disposed on the substrate 110 to protect the plurality of transistors DT and planarize upper portions of the plurality of transistors DT. For example, the first planarization layer 515a can be formed of photoresist or an acrylic-based organic material, but is not limited thereto.

A first connection electrode CE1 electrically connecting the plurality of transistors DT and the first electrode E1 can be disposed on the first planarization layer 515a. The first connection electrode CE1 can be connected to one of the source electrode SE and the drain electrode DE of the plurality of transistors DT through a contact hole provided in the first planarization layer 515a.

A second planarization layer 515b can be disposed on the first connection electrode CE1. The second planarization layer 515b can be formed of the same material as the first planarization layer 515a.

Meanwhile, referring to FIGS. 2 and 8, in the display device 500 according to still another example embodiment of the present disclosure, each of the plurality of touch lines TL can include a first line L1 disposed on the same layer as the plurality of auxiliary electrodes AE and a second line L2 disposed below the first line L1. For example, the first line L1 can be formed of the same material on the same layer as the plurality of auxiliary electrodes AE, and the second line L2 can be formed of the same material on the same layer as the first connection electrode CE1.

Referring to FIGS. 2 and 8 together, in the display device 500 according to still another example embodiment of the present disclosure, the plurality of touch lines TL can extend in the first direction D1 and overlap with the plurality of touch electrodes TS in the first direction D1. In this situation, the plurality of touch lines TL can be electrically connected to only one touch electrode TS among the plurality of touch electrodes TS arranged in the first direction D1.

Referring to FIG. 8, the first line L1 can be disposed to overlap with the touch electrode TS which is electrically connected to the first line L1 among the plurality of touch electrodes TS and the second line L2 can be electrically connected to the first line L1 at an end of the touch electrode TS which is electrically connected to the first line L1 among the plurality of touch electrodes TS.

That is, one touch electrode TS of the plurality of touch electrodes TS can be electrically connected to the first line L1, and at an end thereof, the first line L1 can be electrically connected to the second line L2 disposed below the first line L1.

In this situation, the second line L2 can be electrically connected to the touch driver, and the plurality of touch electrodes TS can be applied with the touch driving signal through the second line L2.

Accordingly, in the display device 500 according to still another example embodiment of the present disclosure, the touch sensing unit can be electrically connected to the touch driving unit using the second line L2 positioned on the same layer as the first connection electrode CE1. In addition, one touch line TL can be electrically connected to only one touch electrode TS and can be easily insulated from other touch electrodes TS.

In the display device 500 according to still another example embodiment of the present disclosure, by applying an in-cell type touch sensing unit in which a touch sensing unit is embedded in a display panel, a decrease in touch performance can be prevented or reduced even if the display device 500 becomes large.

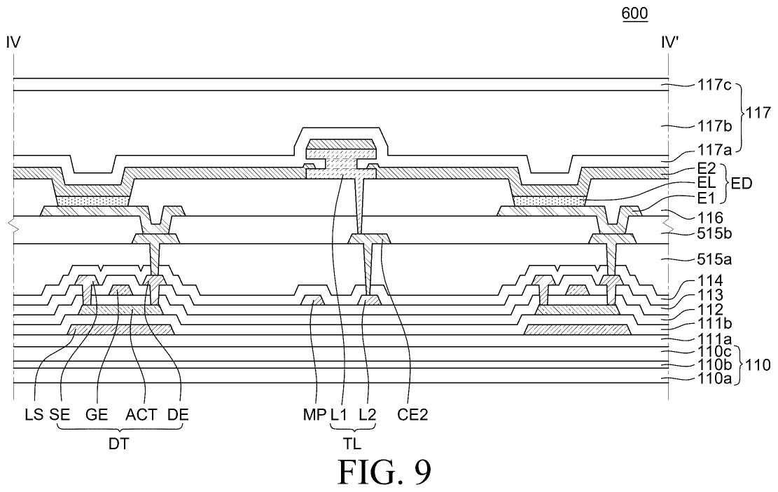

FIG. 9 is a cross-sectional view of a display device according to still another example embodiment of the present disclosure. FIG. 9 is a cross-sectional view illustrating IV-IV′ of FIG. 2 according to another embodiment of the present disclosure. In FIG. 9, the other configuration except for the position of the second line L2 is substantially the same as that in FIG. 8. Therefore, for convenience of description, a redundant description other than the second line L2 will be omitted.

Referring to FIGS. 2 and 9, in the display device 600 according to still another example embodiment of the present disclosure, each of the plurality of touch lines TL can include a first line L1 disposed on the same layer as the plurality of auxiliary electrodes AE and a second line L2 disposed below the first line L1. For example, the first line L1 can be formed of the same material on the same layer as the plurality of auxiliary electrodes AE, and the second line L2 can be located on the same layer as the source electrodes SE and the drain electrodes DE of the plurality of transistors DT.

Referring to FIGS. 2 and 9 together, in the display device 600 according to still another example embodiment of the present disclosure, the plurality of touch lines TL can extend in the first direction D1 and overlap with the plurality of touch electrodes TS in the first direction D1. In this situation, each of the plurality of touch lines TL can be electrically connected to only one touch electrode TS among the plurality of touch electrodes TS arranged in the first direction D1.

Referring to FIG. 9, the first line L1 can be disposed to overlap with the touch electrode TS which is electrically connected to the first line L1 among the plurality of touch electrodes TS and the second line L2 can be electrically connected to the first line L1 at an end of the touch electrode TS which is electrically connected to the first line L1 among the plurality of touch electrodes TS.

That is, one touch electrode TS of the plurality of touch electrodes TS can be electrically connected to the first line L1, and at an end thereof, the first line L1 can be electrically connected to the second line L2 disposed below the first line L1.

In this situation, the second line L2 can be electrically connected to the touch driver, and the plurality of touch electrodes TS can be applied with the touch driving signal through the second line L2.

In this situation, the display device can further include a second connection electrode CE2 disposed on the first planarization layer 515a, made of the same material as the first connection electrode CE1, and electrically connecting the first line L1 and the second line L2. For example, the first line L1, the second line L2, and the second connection electrode CE2 can overlap each other.

For example, when the second connection electrode CE is further included between the first line L1 and the second line L2, the resistance is further lowered, which can improve the touch performance of the display device 600.

Accordingly, in the display device 600 according to still another example embodiment of the present disclosure, the touch sensing unit can be electrically connected to the touch driving unit using the second line L2 positioned on the same layer as the components of the plurality of transistors DT. In addition, one touch line TL can be electrically connected to only one touch electrode TS and can be easily insulated from other touch electrodes TS.

In addition, in the display device 600 according to still another example embodiment of the present disclosure, by applying an in-cell type touch sensing unit in which a touch sensing unit is embedded in the display panel, even if the display device 500 becomes large, a decrease in touch performance can be prevented or reduced.

The example embodiments of the present disclosure can also be described as follows:

According to an aspect of the present disclosure, a display device includes: a substrate including an active area in which a plurality of sub pixels is disposed and a non-active area disposed at an outer periphery of the active area; a plurality of light emitting elements which is disposed in the plurality of sub pixels on the substrate and includes a first electrode, an organic layer, and a second electrode; a bank which is disposed to cover at least a part of the first electrode; a plurality of auxiliary electrodes which is disposed on the bank and electrically connects second electrodes which are adjacent to each other; and a touch sensing unit disposed in the active area on the substrate, and includes a plurality of touch electrodes disposed spaced apart from each other, in which each of the plurality of touch electrodes includes a group of the second electrodes electrically connected by the plurality of auxiliary electrodes, and a plurality of touch lines connected to each of the plurality of touch electrodes, and is formed of the same material as the plurality of auxiliary electrodes.

According to the example embodiment of the present disclosure, the display device can further include a plurality of first spacers disposed on the bank and has an inverted trapezoidal shape, the plurality of touch electrodes can be disposed to be spaced apart from each other in a first direction and a second direction intersecting the first direction, and the plurality of first spacers can be disposed in an area in which the plurality of touch electrodes is spaced apart from each other.

According to an example embodiment of the present disclosure, the display device can further include a plurality of dummy lines disposed on the bank to be covered by a plurality of first spacers, and the plurality of dummy lines can be electrically floated.

According to the embodiment of the present disclosure, the plurality of dummy lines can be formed of the same material on the same layer as the plurality of auxiliary electrodes.

According to the example configuration of the present disclosure, the plurality of touch lines can be disposed on the same layer as the plurality of auxiliary electrodes.

According to an example embodiment of the present disclosure, each of the plurality of touch lines includes a first line electrically connected to the plurality of touch lines among the plurality of touch electrodes and a second line insulated from the plurality of touch lines among the plurality of touch electrodes, and the first line and the second line can be disposed on the same layer.

According to the example embodiment of the present disclosure, the display device can further include a plurality of second spacers disposed on the bank to cover the second line and having an inverted trapezoidal shape.

According to an example embodiment of the present disclosure, the plurality of auxiliary electrodes and the plurality of touch lines can each include a first layer, a second layer on the first layer, and a third layer on the second layer, and a width of the second layer can be smaller than a width of the first layer and a width of the third layer.

According to an example embodiment of the present disclosure, the display device can further include a hole penetrating the bank, and each of the plurality of touch lines can include a first line disposed in the hole and a second line disposed below the first line.

According to the example embodiment of the present disclosure, the first line can be disposed to overlap a touch electrode electrically connected to the first line among the plurality of touch electrodes, and the second line can be electrically connected to the first line at an end of the touch electrode electrically connected to the first line among the plurality of touch electrodes.

According to the example embodiment of the present disclosure, the display device can further include a plurality of transistors disposed on the substrate and electrically connected to the first electrode, and a planarization layer disposed on the plurality of transistors. The second line can be disposed on the same layer as the source electrodes and the drain electrodes of the plurality of transistors.

According to an example embodiment of the present disclosure, each of the plurality of touch lines can include a first line disposed on the same layer as the plurality of auxiliary electrodes and a second line disposed below the first line.

According to the example embodiment of the present disclosure, the first line can be disposed to overlap a touch electrode electrically connected to the first line among the plurality of touch electrodes, and the second line can be electrically connected to the first line at an end of the touch electrode electrically connected to the first line among the plurality of touch electrodes.

According to the example embodiment of the present disclosure, the second line can be disposed under the touch electrode electrically insulated from the second line among the plurality of touch electrodes.

According to the embodiment of the present disclosure, the second line can be disposed to overlap a plurality of auxiliary electrodes.

According to the example embodiment of the present disclosure, the display device can further include a plurality of transistors disposed on the substrate and electrically connected to the first electrode, and a planarization layer disposed on the plurality of transistors. The second line can be disposed on the same layer as the source electrodes and the drain electrodes of the plurality of transistors.

According to the example embodiment of the present disclosure, the display device can further include a plurality of transistors disposed on the substrate, a first planarization layer configured to planarize upper portions of the plurality of transistors, a first connection electrode disposed on the first planarization layer and configured to electrically connect the plurality of transistors and the first electrode, and a second planarization layer disposed on the first planarization layer and the first connection electrode, in which the second line can be disposed on the same layer as the source electrode and the drain electrode of the plurality of transistors.

According to the example embodiment of the present disclosure, the display device can further include a second connection electrode which is disposed on the first planarization layer, is made of the same material as the first connection electrode, and electrically connects the first line and the second line, and the first line, the second line, and the second connection electrode overlap each other.

According to an example embodiment of the present disclosure, a display device can further include: a plurality of transistors disposed on a substrate; a first planarization layer planarizing upper portions of the plurality of transistors; a first connection electrode disposed on the first planarization layer and electrically connecting the plurality of transistors and the first electrode; a second connection electrode disposed on the first planarization layer and made of the same material as the first connection electrode; and a second planarization layer disposed on the first connection electrode and the second connection electrode, in which a second line can be disposed on the same layer as the second connection electrode.

According to an another aspect of the present disclosure, a display device includes a plurality of light emitting elements disposed on a substrate, each of the plurality of light emitting elements including a first electrode, an organic layer, and a second electrode, a bank disposed on the substrate, a plurality of auxiliary electrodes disposed on the bank and configured to electrically connect adjacent second electrodes, and a touch sensing unit including a plurality of touch electrodes and a plurality of touch lines, each of the plurality of touch electrodes includes a group of second electrodes electrically connected to each other by at least one of the plurality of auxiliary electrodes, and the plurality of touch lines are respectively connected to the plurality of touch electrodes and are made of a same material as the plurality of auxiliary electrodes.

According to the example embodiment of the present disclosure, the display device may further include a plurality of first spacers disposed on the bank in an area between adjacent touch electrodes of the plurality of touch electrodes.

According to the example embodiment of the present disclosure, the display device may further include a plurality of dummy lines disposed on the bank and covered by the plurality of first spacers, the plurality of dummy lines are electrically floated and made of a same material as the plurality of auxiliary electrodes.

According to the example embodiment of the present disclosure, the second electrode may be electrically connected to a side surface of an auxiliary electrode among the plurality of auxiliary electrodes, and the auxiliary electrode may have a lower sheet resistance than the second electrode to reduce a voltage drop.

According to the example embodiment of the present disclosure, the touch sensing unit may be configured to recognize a touch using self-capacitance.

According to the example embodiment of the present disclosure, the plurality of auxiliary electrodes may be disposed in an area which does not overlap with the plurality of touch lines.

According to the example embodiment of the present disclosure, the display device may further include a hole passing through the bank in an area where one of the plurality of touch lines connects to one of the plurality of touch electrodes, the one of the plurality of touch electrodes may include a first line disposed in the hole and electrically connected to the one of the plurality of touch electrodes, and a second line disposed below the first line and electrically connected to the first line.

According to the example embodiment of the present disclosure, the display device may further include a plurality of transistors, each of the plurality of transistors including a source electrode and a drain electrode, the first line may be made of the same material as the plurality of auxiliary electrodes, and wherein the second line may be made of a same material as the source electrode and the drain electrode.

Although the example embodiments of the present disclosure have been described in detail with reference to the accompanying drawings, the present disclosure is not limited thereto and can be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a plurality of sub pixels disposed in an active area of a substrate; a plurality of light emitting elements in the plurality of sub pixels, each of the plurality of light emitting elements including a first electrode, an organic layer, and a second electrode;
a bank overlapping with at least a part of the first electrode;
a plurality of auxiliary electrodes disposed on the bank and electrically connecting second electrodes of two adjacent subpixels with each other; and
a touch sensing unit disposed in the active area and including:
a plurality of touch electrodes spaced apart from each other, wherein each of the plurality of touch electrodes includes a group of second electrodes electrically connected to each other by at least one of the plurality of auxiliary electrodes, and
a plurality of touch lines connected to the plurality of touch electrodes, wherein the plurality of touch lines are made of a same material as the plurality of auxiliary electrodes.

2. The display device according to claim 1, further comprising:
a plurality of first spacers disposed on the bank and having an inverted trapezoidal shape,
wherein the plurality of touch electrodes are spaced apart from each other in a first direction and a second direction intersecting the first direction, and
wherein each of the plurality of first spacers is disposed in an area where adjacent touch electrodes among the plurality of touch electrodes are spaced apart from each other.

3. The display device of claim 2, further comprising:
a plurality of dummy lines disposed on the bank and covered by the plurality of first spacers,
wherein the plurality of dummy lines are electrically floated.

4. The display device according to claim 3, wherein the plurality of dummy lines are formed of the same material as the plurality of auxiliary electrodes, and the plurality of dummy lines are disposed on a same layer as the plurality of auxiliary electrodes.

5. The display device according to claim 1, wherein the plurality of touch lines are disposed on a same layer as the plurality of auxiliary electrodes.

6. The display device of claim 5, wherein each of the plurality of touch lines includes a first line segment electrically connected to one touch electrode among the plurality of touch electrodes, and a second line segment that is electrically isolated from remaining touch electrodes among the plurality of touch electrodes, and
wherein the first line segment and the second line segment are disposed on a same layer.

7. The display device according to claim 6, further comprising:
a plurality of second spacers disposed on the bank to cover the second line segments of the plurality of touch lines, and each of the plurality of second spacers having an inverted trapezoidal shape.

8. The display device according to claim 1, wherein each of the plurality of auxiliary electrodes and each of the plurality of touch lines includes a first layer, a second layer on the first layer, and a third layer on the second layer, and
wherein a width of the second layer is smaller than a width of the first layer, and the width of the second layer is smaller than a width of the third layer.

9. The display device of claim 1, further comprising:
a hole penetrating the bank,
wherein each of the plurality of touch lines includes a first line disposed in the hole and a second line disposed below the first line.

10. The display device of claim 9, wherein the first line is disposed to overlap with a touch electrode electrically connected to the first line among the plurality of touch electrodes, and
wherein the second line is electrically connected to the first line at an end of the touch electrode electrically connected to the first line among the plurality of touch electrodes.

11. The display device according to claim 10, further comprising:
a plurality of transistors disposed on the substrate and each of the plurality of transistors being electrically connected to a corresponding first electrode; and
a planarization layer disposed on the plurality of transistors,
wherein the second line is disposed on a same layer as source electrodes and drain electrodes of the plurality of transistors.

12. The display device according to claim 1, wherein each of the plurality of touch lines includes a first line disposed on a same layer as the plurality of auxiliary electrodes, and a second line disposed below the first line.

13. The display device of claim 12, wherein the first line overlaps with a touch electrode electrically connected to the first line among the plurality of touch electrodes, and
wherein the second line is electrically connected to the first line at an end of the touch electrode electrically connected to the first line among the plurality of touch electrodes.

14. The display device according to claim 13, wherein the second line is disposed below a touch electrode electrically insulated from the second line among the plurality of touch electrodes.

15. The display device of claim 14, wherein the second line overlaps with one of the plurality of auxiliary electrodes.

16. The display device of claim 13, further comprising:
a plurality of transistors disposed on the substrate and each of the plurality of transistors being electrically connected to a corresponding first electrode; and
a planarization layer disposed on the plurality of transistors,
wherein the second line is disposed on a same layer as source electrodes and drain electrodes of the plurality of transistors.

17. The display device of claim 13, further comprising:
a plurality of transistors disposed on the substrate;
a first planarization layer planarizing upper portions of the plurality of transistors;
a first connection electrode disposed on the first planarization layer and electrically connecting one of the plurality of transistors to a corresponding first electrode; and
a second planarization layer disposed on the first planarization layer and the first connection electrode,
wherein the second line is disposed on a same layer as source electrodes and drain electrodes of the plurality of transistors.

18. The display device of claim 17, further comprising:
a second connection electrode disposed on the first planarization layer, including a same material as the first connection electrode, and electrically connecting the first line and the second line,
wherein the first line, the second line, and the second connection electrode overlap with each other.

19. The display device of claim 13, further comprising:
a plurality of transistors disposed on the substrate;
a first planarization layer planarizing upper portions of the plurality of transistors;
a first connection electrode disposed on the first planarization layer and electrically connecting one of the plurality of transistors to a corresponding first electrode;
a second connection electrode disposed on the first planarization layer and including a same material as the first connection electrode; and
a second planarization layer disposed on the first connection electrode and the second connection electrode,
wherein the second line is disposed on a same layer as the second connection electrode.
